(19) United States
(12) Patent Application Publication
(10) Pub. No.: US 2025/0098498 A1
(43) Pub. Date: Mar. 20, 2025

(54) DISPLAY APPARATUS AND DISPLAY PANEL

(71) Applicants: Chengdu BOE Optoelectronics Technology Co., Ltd., Chengdu, Sichuan (CN); BOE Technology Group Co., Ltd., Beijing (CN)

(72) Inventors: Bo SHI, Beijing (CN); Taofeng XIE, Beijing (CN)

(21) Appl. No.: 18/558,270

(22) PCT Filed: Apr. 27, 2022
(86) PCT No.: PCT/CN2022/089506

§ 371 Date: Oct. 31, 2023

(51) Int. Cl. H10K 59/80; H10K 59/122

(52) U.S. Cl. CPC H10K 59/8791; H10K 59/122

(57) ABSTRACT

A display apparatus and a display panel. The display panel includes a substrate; a light-emitting unit, which is provided on the substrate; a light-reflecting structure, which is provided on a light-emitting side of the light-emitting unit, where the light-reflecting structure includes a first surface, a second surface and a light-reflecting side surface connected between the first surface and the second surface; the first surface faces the light-emitting unit, the second surface is provided on a side of the first surface away from the light-emitting unit; the light-reflecting side surface includes an inclined area which has a step structure; a light-transmitting structure provided on the light-emitting side of the light-emitting unit and covers at least the inclined area, where a refractive index of the light-reflecting structure is smaller than a refractive index of the light-transmitting structure.

### TECHNICAL FIELD

The present disclosure relates to the field of display technologies, and in particular to a display apparatus and a display panel.

### BACKGROUND

Organic light-emitting diode (OLED) display apparatus has a series of advantages such as all-solid state structure, self-luminescence, fast response, high luminance, full viewing angle, and flexible display, thus becoming a very competitive and promising type of display apparatus currently. However, current OLED display apparatus has the problem of low light extraction efficiency.

### SUMMARY

An object of the present disclosure is to provide a display apparatus and a display panel to improve light extraction efficiency.

According to an aspect of the present disclosure, there is provided a display panel including:
a substrate;
a light-emitting unit disposed on the substrate;
a light-reflecting structure disposed on a light-emitting side of the light-emitting unit, where the light-reflecting structure includes a first surface and a second surface that are opposite each other, and a light-reflecting side surface connected between the first surface and the second surface; the first surface faces the light-emitting unit, the second surface is disposed on a side of the first surface away from the light-emitting unit; the light-reflecting side surface includes an inclined area, and the inclined area has a step structure; and
a light-transmitting structure provided on the light-emitting side of the light-emitting unit and covering at least the inclined area, where the light-reflecting structure has a refractive index less than a refractive index of the light transmitting structure.

Further, the inclined area includes a plurality of inclined regions, and the plurality of inclined regions are distributed in a thickness direction of the substrate. The plurality of inclined regions include at least a first inclined region and a second inclined region. The second inclined region is located on a side of the first inclined region away from the light-emitting unit, and an angle between the second inclined region and the substrate is less than an angle between the first inclined region and the substrate, where in a direction parallel to the substrate, the second inclined region is retracted relative to the first inclined region so that the inclined area forms the step structure.

Further, the angle between the second inclined region and the substrate is greater than or equal to 30° and less than or equal to 60°, and the angle between the first inclined region and the substrate is greater than or equal to 45° and less than 90°.

Further, the light-reflecting structure includes a first light-reflecting layer and a second light-reflecting layer. The first light-reflecting layer includes the first inclined region. The second light-reflecting layer includes the second inclined region. The first light-reflecting layer and the second light-reflecting layer are made of same material.

Further, the refractive index of the light-reflecting structure is in a range of 1.4 to 1.55; and/or
the refractive index of the light-transmitting structure is in a range of 1.6 to 1.75.

Further, the inclined area includes a plurality of inclined regions, and the plurality of inclined regions are distributed in a thickness direction of the substrate. The plurality of inclined regions includes at least a first inclined region and a second inclined region. The second inclined region is located on a side of the first inclined region away from the light-emitting unit, and an angle between the second inclined region and the substrate is equal to an angle between the first inclined region and the substrate; where the second inclined region is retracted relative to the first inclined region in a direction parallel to the substrate so that the inclined area forms the step structure.

The light-reflecting structure includes a first light-reflecting layer and a second light-reflecting layer. The first light-reflecting layer includes the first inclined region. The second light-reflecting layer includes the second inclined region. A refractive index of the first light-reflecting layer is greater than a refractive index of the second light-reflecting layer.

Further, an angle between the second inclined region and the substrate is greater than or equal to 45° and less than 90°.

Further, the refractive index of the first light-reflecting layer is 1.5 to 1.55, and the refractive index of the second light-reflecting layer is 1.4 to 1.45; and/or
The refractive index of the light-transmitting structure is 1.6 to 1.75.

Further, in the direction parallel to the substrate, the distance between the second inclined region and the first inclined region is 0.5 μm to 6 μm.

Further, the display panel further includes:
a pixel defining layer disposed on the substrate and provided with a pixel opening, and the light-emitting unit is disposed in the pixel opening;
where an orthographic projection of the pixel opening on the substrate is located within an orthographic projection of the light-transmitting structure on the substrate, and an orthographic projection of the light-reflecting structure on the substrate is located within an orthographic projection of the pixel-defining layer on the substrate.

Further, the display panel further includes:
a pixel defining layer disposed on the substrate and provided with a pixel opening, and the light-emitting unit is disposed in the pixel opening;
where, at least part of an orthographic projection of the light-reflecting structure on the substrate is located within an orthographic projection of the pixel opening on the substrate.

Further, the display panel further includes:
a pixel defining layer disposed on the substrate and provided with a pixel opening, and the light-emitting unit is disposed in the pixel opening;
where in a direction parallel to the substrate, the light-reflecting structure includes a first portion and a second portion, an orthographic projection of the first portion on the substrate surrounds an orthographic projection of the second portion on the substrate, the orthographic projection of the first portion on the substrate surrounds an orthographic projection of the pixel opening on the substrate, and at least a part of the orthographic projection of the second portion on the substrate is located within the orthographic projection of the pixel opening on the substrate.

Further, the second portion is in a strip structure and extends in a direction parallel to the substrate.

Further, a side of the light-transmitting structure is provided with a concave portion, the side of the light-transmitting structure provided with the concave portion faces the light-emitting unit or is away from the light-emitting unit, and the light-reflecting structure is disposed in the concave portion.

Further, the display panel further includes:
an encapsulation layer, disposed on a side of the light-emitting unit, where the light-transmitting structure is disposed on a side of the encapsulation layer away from the light-emitting unit or the light-transmitting structure is disposed between the encapsulation layer and the light-emitting unit.

According to an aspect of the present disclosure, a display apparatus is provided, including the display panel.

In the display panel and display apparatus of the present disclosure, the light-reflecting side surface of the light-reflecting structure includes an inclined area, and the light-transmitting structure at least covers the inclined area. On one hand, when emitted light of the display panel in a large view angle is projected from the light-transmitting structure into the inclined area, the emitted light will reflect, so that the emitted light of the display panel in the large view angle will change to the emitted light in a narrow view angle, so as to avoid the total reflection of the emitted light on the emission surface of the display panel, reduce the waste of light and improve the light extraction efficiency. On the other hand, since the refractive index of the light-reflecting structure is less than that of the light-transmitting structure, in the present disclosure, by adjusting the angle of the inclined area, the emitted light undergoes total reflection in the inclined area to further avoid the waste of light and improve the light efficiency.

### BRIEF DESCRIPTION OF THE DRAWINGS

FIG. 1 is a schematic diagram of light emission of a display panel in related art.

FIG. 2 is a schematic diagram of a display panel according to embodiments of the present disclosure.

FIG. 3 is a schematic diagram of a light-reflecting structure according to the embodiments of the present disclosure.

FIG. 4 is a schematic diagram of another display panel according to the embodiments of the present disclosure.

FIG. 5 is a schematic diagram of yet another display panel according to the embodiments of the present disclosure.

FIG. 6 is a schematic diagram of a pixel defining layer according to the embodiments of the present disclosure.

FIGS. 7 to 9 are schematic diagrams of a second portion of the light-reflecting structure and a pixel opening according to the embodiments of the present disclosure.

Description of reference numerals: 1 substrate; 2 light-emitting structure; 3 glass cover; 4 light-reflecting structure; 40 inclined area; 401 first inclined region; 402 second inclined region; 41 first light-reflecting layer; 42 second light-reflecting layer; 43 first surface; 44 second surface; 5 light-transmitting structure; 6 drive circuit layer; 7 planarization layer; 8 pixel defining layer; 81 pixel opening; 9 light-emitting unit; 91 anode layer; 92 light-emitting material layer; 93 cathode layer; 10 encapsulation layer; 100 first portion; 200 second portion.

### DETAILED DESCRIPTION OF THE EMBODIMENTS

Exemplary embodiments will be described in detail here, with the illustrations thereof represented in the drawings. When the following descriptions involve the drawings, the same numbers in different drawings refer to the same or similar elements unless otherwise indicated. The embodiments described in the following exemplary embodiments do not represent all embodiments consistent with the present disclosure. Rather, they are merely examples of apparatuses consistent with some aspects of the present disclosure as detailed in the appended claims.

The terms used in the present disclosure are only for the purpose of describing particular embodiments, and are not intended to limit the present disclosure. Unless otherwise defined, the technical terms or scientific terms used in the present disclosure shall have the common meaning understood by those with general skills in the field of the present disclosure. The “first”, “second” and the like used in the present disclosure and claims do not indicate any order, quantity or importance, but are only used to distinguish different components. Similarly, similar words such as “a” or “one” do not mean quantitative restriction, but mean the existence of at least one. “Multiple” or “several” means two or more. Unless otherwise indicated, the words “front”, “rear”, “lower” and/or “upper” are only for convenience of explanation, not limited to a position or a spatial orientation. Similar words such as “including” or “comprising” mean that the elements or objects listed before “including” or “comprising” cover the elements or objects listed after “including” or “comprising” and their equivalents, and do not exclude other elements or objects. Similar terms such as “connect” or “bond” are not limited to physical or mechanical connection, including electrical connection, whether direct or indirect. The singular forms of “one”, “the” and “said” used in the present disclosure and the appended claims are also intended to include the majority forms, unless the context clearly indicates other meanings. It should also be understood that the term “and/or” used herein refers to and includes any or all possible combinations of one or more associated listed items.

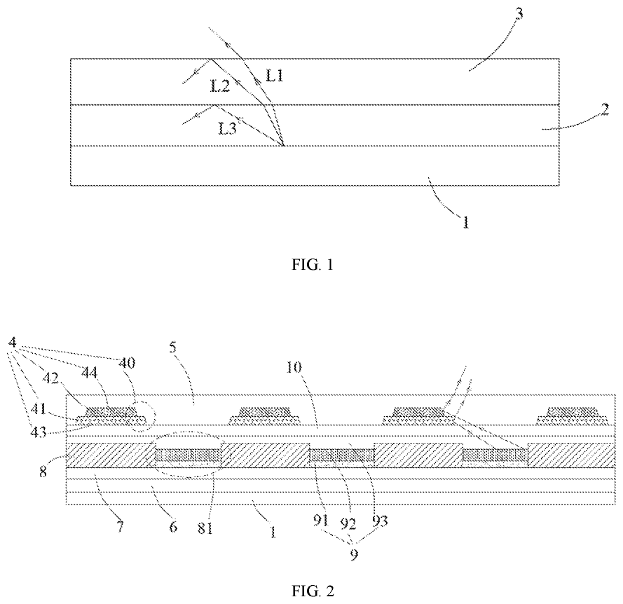

In related arts, as shown in FIG. 1, a display panel includes a substrate 1, a light-emitting structure 2 and a glass cover 3. The light-emitting structure 2 is disposed on the substrate 1, and the glass cover 3 is disposed on a side of the light-emitting structure 2 away from the substrate 1. The light-emitting structure 2 may include light-emitting units, an encapsulation layer, and the like. A light-emitting surface of the display panel is a surface of the glass cover 3 away from the substrate 1. When light reaches the light-emitting surface of the display panel, the light LI normally emits. Since a refractive index of the glass cover 3 is greater than a refractive index of external environment (air), and an incident angle of the light L2 is equal to or greater than the critical angle of total reflection, the light L2 will undergo total internal reflection, resulting in low overall light extraction efficiency. In addition, since a refractive index of the light-emitting structure 2 is also greater than the refractive index of the glass cover 3, when the light L3 is incident on an interface between the light-emitting structure 2 and the glass cover 3, if the incident angle is equal to or greater than the critical angle of total reflection, total internal reflection will also occur.

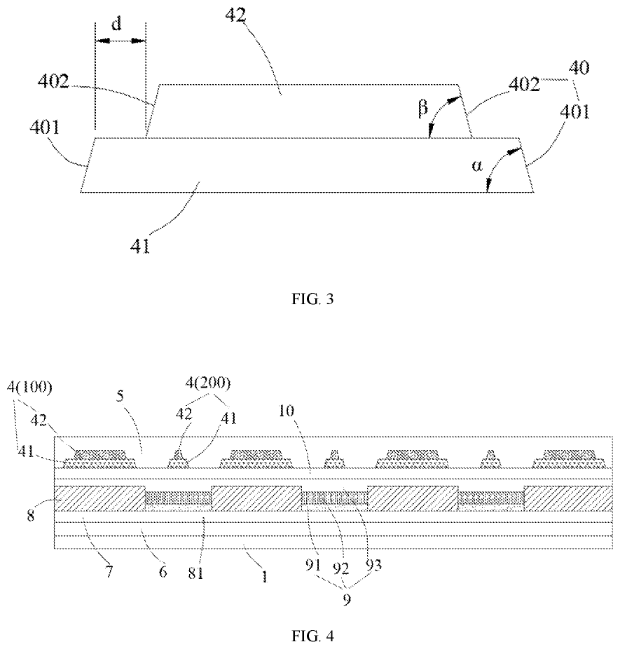

Embodiments of the present disclosure provide a display panel. As shown in FIGS. 2 and 3, the display panel may include a substrate 1, a light-emitting unit 9, a light-transmitting structure 5 and a light-reflecting structure 4.

The light-emitting unit 9 is disposed on the substrate 1. The light-reflecting structure 4 is disposed on a light-emitting side of the light-emitting unit 9. The light-reflecting structure 4 includes a first surface 43 and a second surface 44 that are opposite to each other, and a light-reflecting side surface connected between the first surface 43 and the second surface 44. The first surface 43 faces the light-emitting unit 9, and the second surface 44 is disposed on the side of the first surface 43 away from the light-emitting unit 9. The light-reflecting side surface includes an inclined area 40. The inclined area 40 has a step structure. The light-transmitting structure 5 is disposed on the light-emitting side of the light-emitting unit 9, and at least covers the inclined area 40. A refractive index of the light-reflecting structure 4 is less than that of the light-transmitting structure 5.

In the display panel of the embodiments of the present disclosure, the light-reflecting side surface of the light-reflecting structure 4 includes an inclined area 40, and the light-transmitting structure 5 covers at least the inclined area 40. On one hand, when the emitted light of the display panel in a large view angle is emitted from the light-transmitting structure 5 into the inclined area 40, the emitted light will reflect, so that the emitted light of the display panel in the large view angle changes to the emitted light in a narrow view angle, avoiding the total reflection of the emitted light on the emission surface of the display panel, reducing the waste of light, and improving the light extraction efficiency. On the other hand, since the refractive index of the light-reflecting structure 4 is less than that of the light-transmitting structure 5, in the present disclosure, the angle of the inclined area 40 may be adjusted to make total reflection of the emitted light in the inclined area 40 happen, further avoiding the waste of light and improving the light extraction efficiency.

Each portion of the display panel of the embodiments of the present disclosure will be described in detail below.

As shown in FIG. 2, the substrate 1 may be a rigid substrate. The rigid substrate may be glass substrate or polymethyl methacrylate (PMMA) substrate. However, the substrate 1 may also be a flexible substrate. The flexible substrate may be polyethylene terephthalate (PET) substrate, polyethylene naphthylate two formic acid glycol ester (PEN) substrate or polyimide (PI) substrate.

As shown in FIG. 2, the display panel may further include a drive circuit layer 6 disposed on the substrate 1. The drive circuit layer 6 may include a drive transistor. The drive transistor may be a thin film transistor, but the embodiments of the present disclosure are not limited to this. The thin film transistor may be a top-gate thin film transistor, however, the thin film transistor may also be a bottom-gate thin film transistor. Taking the thin film transistor being a top-gate thin film transistor as an example, the thin film transistor includes an active layer, a gate insulating layer, a gate, an interlayer insulating layer, a source and a drain. The active layer is disposed on the substrate 1. The gate insulating layer is disposed on the substrate 1 and covers the active layer. The gate is disposed on the side of the gate insulating layer away from the substrate 1. The interlayer insulating layer is disposed on the gate insulating layer and covers the gate. The source and drain are disposed on the interlayer insulating layer and connected to the active layer through via holes penetrating through the interlayer insulating layer and the gate insulating layer. The display panel according to the present disclosure further includes a planarization layer 7 and a pixel defining layer 8. The planarization layer 7 covers the source, the drain and the interlayer insulating layer of the thin film transistor. The pixel defining layer 8 is disposed on a side of the planarization layer 7 away from the substrate 1. As shown in FIG. 6, the pixel defining layer 8 may be provided with pixel openings 81. There may be a plurality of pixel openings 81.

As shown in FIG. 2, the light-emitting unit 9 is disposed on the substrate 1. Specifically, the light-emitting unit 9 may be disposed in the pixel openings 81. For example, there are a plurality of pixel openings 81, there may also be a plurality of light-emitting units 9, and the plurality of light-emitting units 9 are disposed in the plurality of pixel openings 81 in a one-to-one correspondence. The plurality of light-emitting units 9 may include red light-emitting units, green light-emitting units and blue light-emitting units. Each of the light-emitting units 9 includes an anode layer 91, a light-emitting material layer 92 and a cathode layer 93. The anode layer 91 is disposed on the planarization layer 7 exposed by the pixel opening 81. The cathode layer 93 is disposed on a side of the anode layer 91 away from the substrate 1. The light-emitting material layer 92 is disposed between the anode layer 91 and the cathode layer 93. The light-emitting material layer 92 may be an organic electroluminescent material layer, but the embodiments of the present disclosure are not limited to this. The anode layer 91 may be electrically connected to the source or drain of the thin film transistor through a via hole penetrating through the planarization layer 7. An encapsulation layer 10 may be disposed on one side of the light-emitting unit 9 and the pixel defining layer 8. The encapsulation layer 10 may be a thin film encapsulation layer (TFE), but the embodiments of the present disclosure have no special restrictions on this. The light-emitting side of the light-emitting unit 9 may be a side of the light-emitting unit 9 facing the substrate 1. In this case, the substrate 1 needs to be a transparent substrate or a light-transmitting substrate. However, the light-emitting side of the light-emitting unit 9 may also be the side of the light-emitting unit 9 away from the substrate 1.

As shown in FIGS. 2 and 3, the light-reflecting structure 4 is disposed on the light-emitting side of the light-emitting unit 9. Taking the light-emitting side of the light-emitting unit 9 being the side of the light-emitting unit 9 away from the substrate 1 as an example, the light-reflecting structure 4 may be disposed on the side of the pixel defining layer 8 away from the substrate 1. The light-reflecting structure 4 may be located on the side of the encapsulation layer 10 away from the substrate 1. However, the light-reflecting structure 4 may also be located between the encapsulation layer 10 and the pixel defining layer 8. The light-reflecting structure 4 includes a first surface 43, a second surface 44 and a light-reflecting side surface. The first surface 43 and the second surface 44 are disposed oppositely, and the light-reflecting side surface is connected between the first surface 43 and the second surface 44. The first surface 43 faces the light-emitting unit 9, and the second surface 44 is disposed on the side of the first surface 43 away from the light-emitting unit 9. The first surface 43 may be parallel or substantially parallel to the substrate 1. The second surface 44 may be parallel or substantially parallel to the substrate 1. The light-reflecting side surface includes an inclined area 40. The inclined area 40 is inclined relative to a direction perpendicular to the substrate 1, and the angle between the inclined area 40 and the substrate 1 is an acute angle, that is, a slope angle of the inclined area 40 is an acute angle. The angle between the inclined area 40 and the substrate 1 may be greater than or equal to 30° and less than 90°. The refractive index of the light-reflecting structure 4 may be 1.4 to 1.55, such as 1.4, 1.45, 1.5, or 1.55.

As shown in FIGS. 2 and 3, the inclined area 40 may include a plurality of inclined regions, and the plurality of inclined regions are distributed in a thickness direction of the substrate 1. Angles between the plurality of inclined regions and the substrate 1 may be equal, or not equal. The light-reflecting structure 4 includes a plurality of light-reflecting layers in the direction perpendicular to the substrate 1, and a side surface of each light-reflecting layer forms a part of the light-reflecting side surface. A thickness of the light-reflecting layer may be 1 μm to 3 μm, such as 1 μm, 2 μm, or 3 μm. The section area of the light-reflecting layer increases in the direction towards/approaching the light-emitting unit 9, so that the side surface of the light-reflecting layer forms an inclined region as described above. As shown in FIG. 3, the above plurality of inclined regions at least include a first inclined region 401 and a second inclined region 402, which is located on a side of the first inclined region 401 away from the light-emitting unit 9. Specifically, the above plurality of light-reflecting layers at least include a first light-reflecting layer 41 and a second light-reflecting layer 42. The second light-reflecting layer 42 is located on a side of the first light-reflecting layer 41 away from the light-emitting unit 9. Side surfaces of the first light-reflecting layer 41 form the first inclined region 401, and side surfaces of the second light-reflecting layer 42 form the second inclined region 402. In addition, in a direction parallel to the substrate 1, the second inclined region 402 may be retracted relative to the first inclined region 401, namely, a distance between the second inclined region 402 and the light-reflecting structure 4 is less than a distance between the first inclined region 401 and the light-reflecting structure 4. In the direction parallel to the substrate 1, a distance between the second inclined region 402 and the first inclined region 401 is greater than zero in the direction parallel to the substrate 1, so that the inclined area 40 forms the step structure. Specifically, as shown in FIG. 3, the distance d between the second inclined region 402 and the first inclined region 401 in the direction parallel to the substrate 1 may be 0.5 μm to 6 μm for example, 0.5 μm, 1 μm, 1.5 μm, 2 μm, 3 μm, 4 μm, 5 μm, or 6 μm.

As shown in FIGS. 2 and 3, in some embodiments of the present disclosure, the angle β between the second inclined region 402 and the substrate 1 is less than the angle α between the first inclined region 401 and the substrate 1. The angle β between the second inclined region 402 and the substrate 1 is greater than or equal to 30° and less than or equal to 60°, such as 30°, 45°, 50°, or 60°. The angle α between the first inclined region 401 and the substrate 1 is greater than 45° and equal to and less than 90°, such as 45°, 55°, 72°, 80°, or the like. Since the angle β between the second inclined region 402 and the substrate 1 is less than the angle α between the first inclined region 401 and the substrate 1, it may be possible to increase the incidence angle of the light emitted from a far emission position to the second inclined region 402, and increase the amount of light undergoing total reflection, and thus improve the light extraction efficiency. In other embodiments of the present disclosure, the angle β between the second inclined region 402 and the substrate 1 is equal to the angle α between the first inclined region 401 and the substrate 1. The angle β between the second inclined region 402 and the substrate 1 is greater than or equal to 45° and less than 90°, such as 45°, 55°, 70°, 80°, or the like.

As shown in FIGS. 2 and 3, for example, the first light-reflecting layer 41 includes the first inclined region 401 and the second light-reflecting layer 42 includes the second inclined region 402, when the angle β between the second inclined region 402 and the substrate 1 is less than the angle α between the first inclined region 401 and the substrate 1, the refractive index of the second light-reflecting layer 42 may be less than the refractive index of the first light-reflecting layer 41. However, the refractive index of the second light-reflecting layer 42 may also be equal to the refractive index of the first light-reflecting layer 41. For example, the refractive index of the second light-reflecting layer 42 and the refractive index of the first light-reflecting layer 41 are both 1.4 to 1.55, but the present disclosure is not limited to this. The refractive index of the second light-reflecting layer 42 may also be greater than the refractive index of the first light-reflecting layer 41. In a case where the refractive index of the second light-reflecting layer 42 is equal to the refractive index of the first light-reflecting layer 41, the material of the second light-reflecting layer 42 and the material of the first light-reflecting layer 41 may be the same or different. In a case where the angle β between the second inclined region 402 and the substrate 1 is equal to the angle α between the first inclined region 401 and the substrate 1, the refractive index of the second light-reflecting layer 42 may be less than the refractive index of the first light-reflecting layer 41. For example, the refractive index of the second light-reflecting layer 42 is 1.4 to 1.45 and the refractive index of the first light-reflecting layer 41 is 1.5 to 1.55. In this way, since the refractive index of the second light-reflecting layer 42 is smaller than the first light-reflecting layer 41, its critical angle of total reflection is also smaller, which increases the amount of light that undergoes total reflection and improves the light extraction gain.

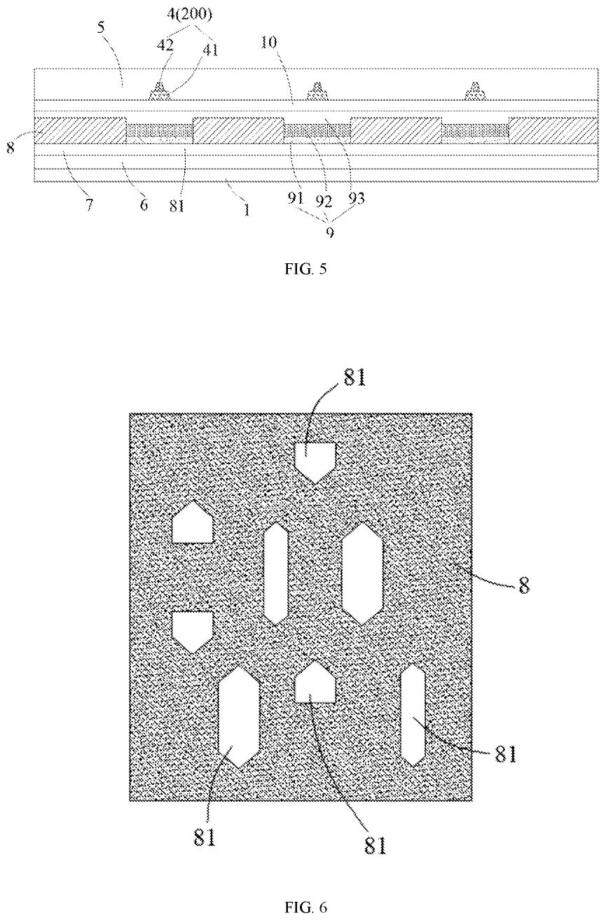

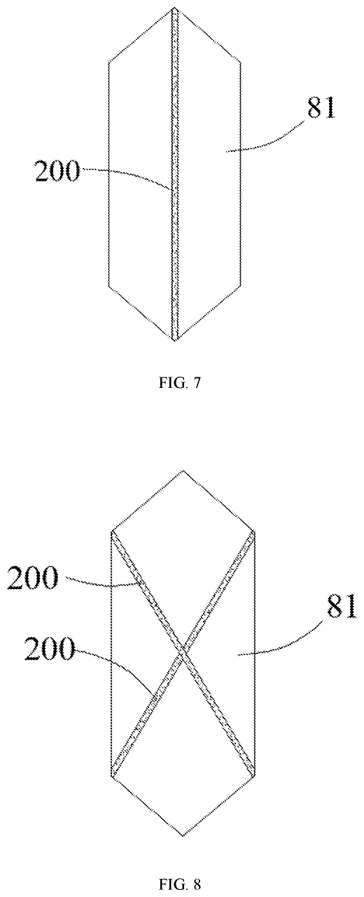

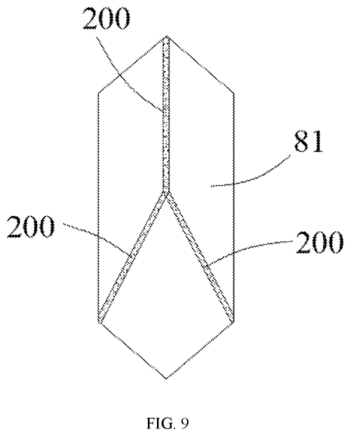

As shown in FIG. 2, an orthographic projection of the light-reflecting structure 4 on the substrate 1 is located within the orthographic projection of the pixel defining layer 8 on the substrate 1. In other embodiments of the present disclosure, as shown in FIGS. 4 and 5, at least part of the orthographic projection of the light-reflecting structure 4 on the substrate 1 is located within the orthographic projection of the pixel opening 81 on the substrate 1. For example, as shown in FIG. 4, in the direction parallel to the substrate 1, the light-reflecting structure 4 includes a first portion 100 and a second portion 200. An orthographic projection of the first portion 100 on the substrate 1 surrounds an orthographic projection of the second portion 200 on the substrate 1 and the orthographic projection of the first portion 100 on the substrate 1 surrounds the orthographic projection of the pixel opening 81 on the substrate 1, and the orthographic projection of the first portion 100 on the substrate 1 is located within the orthographic projection of the pixel defining layer 8 on the substrate 1. At least part of the orthographic projection of the second portion 200 on the substrate 1 is located within the orthographic projection of the pixel opening 81 on the substrate 1. However, as shown in FIG. 5, the light-reflecting structure 4 of the present disclosure may only include the second portion 200 without setting the first portion 100, namely, the orthographic projection of the light-reflecting structure 4 on the substrate 1 is located within the orthographic projection of the pixel opening 81 on the substrate 1. The number of the second portion 200 may be one, two, three, four or more. As shown in FIG. 7, the second portion 200 may be in a strip structure and extend in a direction parallel to the substrate 1. The second portion 200 in the strip structure may be in a shape of straight or broken line, however, it can also be curved, such as in a shape of wavy line. As shown in FIG. 7, for example, the number of the second portion 200 is one, both ends of the second portion 200 in a strip structure are connected to the inner side of the first portion 100, and the second portion 200 may divide the pixel opening 81 into two regions. As shown in FIG. 8, for example, the number of the second portion 200 is two, the two second portions 200 are disposed crosswise, and both ends of each second portion 200 are connected to the inner side of the first portion 100, and the two second portions 200 may divide the pixel opening 81 into four regions, where the two second portions 200 may divide the pixel opening 81 into four regions equally. As shown in FIG. 9, for example, the number of the second portion 200 is three, one end of each of the three second portions 200 is connected together, the other end of each of the three second portions 200 is connected to the inner side of the first portion 100, and the three second portions 200 may divide the pixel opening 81 into three regions, where the three second portions 200 may divide the pixel opening 81 into three regions equally. As shown in FIG. 3, for the first portion 100 of the light-reflecting structure 4, in the direction parallel to the substrate 1, the distance d between the second inclined region 402 and the first inclined region 401 of the first portion 100 may be 2 μm to 6 μm; for the second portion 200 of the light-reflecting structure 4, in the direction parallel to the substrate 1, the distance d between the second inclined region 402 and the first inclined region 401 of the second portion 200 is 0.5 μm to 1.5 μm. In addition, the width of the first light-reflecting layer 41 in the second portion 200 in a strip structure is 4 μm to 6 μm and the width of the second light-reflecting layer 42 in the second portion 200 in a strip structure is 3 μm to 5 μm.

As shown in FIG. 2, the light-transmitting structure 5 is provided on the light-emitting side of the light-emitting unit 9. For example, the light-emitting side of the light-emitting unit 9 is the side of the light-emitting unit 9 away from the substrate 1, the light-transmitting structure 5 is provided on the side of the pixel defining layer 8 away from the substrate 1. The light-transmitting structure 5 may be provided on the side of the encapsulation layer 10 away from the substrate 1, however, the light-transmitting structure 5 may also be provided between the encapsulation layer 10 and the pixel defining layer 8. The material of the light-transmitting structure 5 may include ink, photoresist, or the like.

As shown in FIG. 2, the light-transmitting structure 5 covers at least the inclined area 40 of the light-reflecting structure 4, where one side of the light-transmitting structure 5 may be provided with a concave portion. The concave portion may be provided on the side of the light-transmitting structure 5 facing the light-emitting unit 9, however, the concave portion may be provided on the side of the light-transmitting structure 5 away from the light-emitting unit 9. The light-reflecting structure 4 may be provided in the concave portion. The light-reflecting structure 4 may or may not extend out of the concave portion. In addition, the concave portion may also penetrate through the light-transmitting structure 5 in a direction perpendicular to the substrate 1. In other embodiments of the present disclosure, the light-transmitting structure 5 may enclose the light-reflecting structure 4.

As shown in FIG. 2, the refractive index of the light-transmitting structure 5 is greater than the refractive index of the light-reflecting structure 4. The light-transmitting structure 5 may have a refractive index of 1.6 to 1.75, such as 1.6, 1.65, 1.7, or 1.75. When light enters a low refractive index material from a high refractive index material, total reflection may occur if the incident angle is greater than the critical angle of total reflection. The refractive index of the light-reflecting structure 4 is set to be less than the refractive index of the light-transmitting structure 5 in the present disclosure, and in turn, total reflection of light is achieved by adjusting the angle of incident light to reduce energy loss and improve light extraction efficiency in the present disclosure. In addition, in the direction perpendicular to the substrate 1, the light-transmitting structure 5 may include a first structural surface and a second structural surface that are opposite to each other. The first structural surface is provided between the second structural surface and the light-emitting unit 9. The first structural surface may be flush with the first surface 43 of the light-reflecting structure 4, however, the first structural surface may be misaligned with the first surface 43. For example, the first structural surface is set on the side of the first surface 43 away from or proximate to the light-emitting unit 9. The second structural surface may be flush with the second surface 44 of the light-reflecting structure 4, however, the second structural surface may be misaligned with the second surface 44. For example, the second structural surface is set on the side of the second surface 44 away from or proximate to the light-emitting unit 9.

### PERFORMANCE TESTING

### Comparative Example I

The light-reflecting structure 4 in the structure shown in FIG. 2 is eliminated, and the remaining structure is used as the test structure for Comparative Example I.

### Test Example I

For the structure shown in FIG. 2, the refractive index of the first light-reflecting layer 41 is set to be equal to the refractive index of the second light-reflecting layer 42, the angle between the first inclined region 401 of the first light-reflecting layer 41 and the substrate 1 is 55°, and the angle between the second inclined region 402 of the second light-reflecting layer 42 and the substrate 1 is 45°. Compared with Comparative Example I, the light extraction gain of Test Example I is increased by 17.1%.

### Test Example II

Compared with Test Example I, the difference of Test Example II is that the refractive index of the first light-reflecting layer 41 and the refractive index of the second light-reflecting layer 42 are set unequal, with the refractive index of the first light-reflecting layer 41 being 1.5 and the refractive index of the second light-reflecting layer 42 being 1.4, and the angle between the first inclined region 401 and the substrate 1 is equal to the angle between the second inclined region 402 and the substrate 1. Compared with Comparative Example I, the light extraction gain of Test Example II is increased by 17.3%.

### Test Example III

In Test Example III, the step structure is not provided in the inclined area 40 of the light-reflecting structure 4. Compared with Comparative Example I, the light extraction gain of Test Example III is increased by 12.5%.

The embodiments of the present disclosure further provides a display apparatus. The display apparatus may include a display panel as described in any of the above embodiments. The display apparatus may be a cell phone, a tablet computer, a television, and the like. Since the display panel included in the display apparatus of the embodiments of the present disclosure is the same as the display panel in the embodiments of the above-mentioned display panel, they have the same beneficial effect, which is not repeated in the present disclosure.

The above embodiments are only preferred embodiments of the present disclosure, and do not impose any formal limitation on the present disclosure. The present disclosure has been disclosed the above preferred embodiments, which is not intended to limit the present disclosure. Any person skilled in the art, within the scope of the technical solutions of the present disclosure, uses the above-revealed technical content to make some changes or be modified into equivalent embodiments with equivalent changes. However, any simple revisions, equivalent changes and modifications made to the above embodiments based on the technical substance of the present disclosure, without departing from the content of the technical solutions of the present disclosure, still fall within the scope of the technical solutions of the present disclosure.

1. A display panel, comprising:
a substrate;
a light-emitting unit, disposed on the substrate;
a light-reflecting structure, disposed on a light-emitting side of the light-emitting unit, wherein the light-reflecting structure comprises a first surface and a second surface that are opposite to each other, and a light-reflecting side surface connected between the first surface and the second surface; the first surface faces the light-emitting unit, the second surface is disposed on a side of the first surface away from the light-emitting unit; the light-reflecting side surface comprises an inclined area, and the inclined area has a step structure; and
a light-transmitting structure, provided on the light-emitting side of the light-emitting unit and covering at least the inclined area, wherein the light-reflecting structure has a refractive index smaller than a refractive index of the light-transmitting structure.

2. The display panel according to claim 1, wherein the inclined area comprises a plurality of inclined regions, and the plurality of inclined regions are distributed in a thickness direction of the substrate;
the plurality of inclined regions comprise at least a first inclined region and a second inclined region, the second inclined region is located on a side of the first inclined region away from the light-emitting unit, and an angle between the second inclined region and the substrate is smaller than an angle between the first inclined region and the substrate;
wherein the second inclined region is retracted relative to the first inclined region in a direction parallel to the substrate so that the inclined area forms the step structure.

3. The display panel according to claim 2, wherein the angle between the second inclined region and the substrate is greater than or equal to 30° and less than or equal to 60°, and the angle between the first inclined region and the substrate is greater than or equal to 45° and less than 90°.

4. The display panel according to claim 2, wherein the light-reflecting structure comprises a first light-reflecting layer and a second light-reflecting layer, the first light-reflecting layer comprises the first inclined region, the second light-reflecting layer comprises the second inclined region, and the first light-reflecting layer is of a same material as the second light-reflecting layer.

5. The display panel according to claim 1, wherein the refractive index of the light-reflecting structure is in a range of 1.4 to 1.55; and/or
the refractive index of the light-transmitting structure is in a range of 1.6 to 1.75.

6. The display panel according to claim 1, wherein the inclined area comprises a plurality of inclined regions, and the plurality of inclined regions are distributed in a thickness direction of the substrate;
the plurality of inclined regions comprise at least a first inclined region and a second inclined region, the second inclined region is located on a side of the first inclined region away from the light-emitting unit, and an angle between the second inclined region and the substrate is equal to an angle between the first inclined region and the substrate; wherein the second inclined region is retracted relative to the first inclined region in a direction parallel to the substrate so that the inclined area forms the step structure;
the light-reflecting structure comprises a first light-reflecting layer and a second light-reflecting layer, the first light-reflecting layer comprises the first inclined region and the second light-reflecting layer comprises the second inclined region, a refractive index of the first light-reflecting layer is greater than a refractive index of the second light-reflecting layer.

7. The display panel according to claim 6, wherein the angle between the second inclined region and the substrate is greater than or equal to 45° and less than 90°.

8. The display panel according to claim 6, wherein the refractive index of the first light-reflecting layer is in a range of 1.5 to 1.55 and the refractive index of the second light-reflecting layer is in a range of 1.4 to 1.45; and/or
the refractive index of the light-transmitting structure is in a range of 1.6 to 1.75.

9. The display panel according to claim 2, wherein in the direction parallel to the substrate, a distance from the second inclined region to the first inclined region is in a range of 0.5 μm to 6 μm.

10. The display panel according to claim 1, wherein the display panel further comprises:
a pixel defining layer, disposed on the substrate and provided with a pixel opening, the light-emitting unit being disposed in the pixel opening;
wherein an orthographic projection of the pixel opening on the substrate is located within an orthographic projection of the light-transmitting structure on the substrate, and an orthographic projection of the light-reflecting structure on the substrate is located within an orthographic projection of the pixel-defining layer on the substrate.

11. The display panel according to claim 1, wherein the display panel further comprises:
a pixel defining layer, disposed on the substrate and provided with a pixel opening, the light-emitting unit being disposed in the pixel opening;
wherein at least part of an orthographic projection of the light-reflecting structure on the substrate is located within an orthographic projection of the pixel opening on the substrate.

12. The display panel according to claim 1, wherein the display panel further comprises:
a pixel defining layer, disposed on the substrate and provided with a pixel opening, the light-emitting unit being disposed in the pixel opening;
wherein in a direction parallel to the substrate, the light-reflecting structure comprises a first portion and a second portion, an orthographic projection of the first portion on the substrate surrounds an orthographic projection of the second portion on the substrate, the orthographic projection of the first portion on the substrate surrounds an orthographic projection of the pixel opening on the substrate, and at least a part of the orthographic projection of the second portion on the substrate is located within the orthographic projection of the pixel opening on the substrate.

13. The display panel according to claim 12, wherein the second portion is in a strip structure and extends in a direction parallel to the substrate.

14. The display panel according to claim 1, wherein on a side the light-transmitting structure is provided with a concave portion, and the side of the light-transmitting structure provided with the concave portion faces the light-emitting unit or is away from the light-emitting unit, and the light-reflecting structure is provided in the concave portion.

15. The display panel according to claim 14, wherein the display panel further comprises:
an encapsulation layer, disposed on a side of the light-emitting unit, wherein the light-transmitting structure is disposed on a side of the encapsulation layer away from the light-emitting unit or the light-transmitting structure is disposed between the encapsulation layer and the light-emitting unit.

16. A display apparatus, comprising the display panel of claim 1.

17. The display panel according to claim 6, wherein in the direction parallel to the substrate, a distance from the second inclined region to the first inclined region is in a range of 0.5 μm to 6 μm.

18. The display panel according to claim 7, wherein the refractive index of the first light-reflecting layer is in a range of 1.5 to 1.55 and the refractive index of the second light-reflecting layer is in a range of 1.4 to 1.45; and/or
the refractive index of the light-transmitting structure is in a range of 1.6 to 1.75.

19. The display panel according to claim 3, wherein the refractive index of the light-reflecting structure is in a range of 1.4 to 1.55; and/or
the refractive index of the light-transmitting structure is in a range of 1.6 to 1.75.

20. The display panel according to claim 4, wherein the refractive index of the light-reflecting structure is in a range of 1.4 to 1.55; and/or
the refractive index of the light-transmitting structure is in a range of 1.6 to 1.75.
